(19) United States
(12) Patent Application Publication
(10) Pub. No.: US 2025/0318381 A1
(43) Pub. Date: Oct. 9, 2025

(54) DISPLAY DEVICE

(71) Applicant: Samsung Display Co., Ltd., Yongin-si (KR)

(72) Inventors: HANSOL KIM, Yongin-si (KR); JIN-YUP KIM, Yongin-si (KR); HYUNWOO KIM, Yongin-si (KR); CHANG-YEOL LEE, Yongin-si (KR); YOUNGJIN CHO, Yongin-si (KR)

(21) Appl. No.: 19/052,561

(22) Filed: Feb. 13, 2025

(30) Foreign Application Priority Data
Apr. 3, 2024 (KR) 10-2024-0045348

(51) Int. Cl. H10K 59/131; H01L 23/60; H10K 59/121

(52) U.S. Cl. CPC H10K 59/131; H01L 23/60; H10K 59/1213

(57) ABSTRACT

A display device includes data line electrically connected to respective pixels, scan line, a scan driver electrically connected to the scan line, electrostatic discharge protection circuit electrically connected to the data line, and a first line configured to receive a first voltage and electrically connected to the scan line and the electrostatic discharge protection circuit. The first line crosses with a second line, the first line includes a bridge electrode, the bridge electrode is under an uppermost electrode constituting the electrostatic discharge protection circuit, and the line portion is on a same layer as or under the uppermost electrode constituting the electrostatic discharge protection circuit.

### CROSS-REFERENCE TO RELATED APPLICATIONS

The present application claims priority to and the benefit of Korean Patent

Application No. 10-2024-0045348, filed on Apr. 3, 2024, in the Korean Intellectual Property Office, the entire disclosure of which is incorporated herein by reference.

### BACKGROUND

Aspects of some embodiments of the present disclosure relate to a display device.

A display device includes a display panel including a plurality of pixels for displaying images, a scan driver for providing scan signals to the pixels, a data driver for providing data voltages to the pixels, and a timing controller for controlling the scan driver and the data driver.

The scan driver outputs scan signals in response to a scan control signal provided from the timing controller. The data driver outputs data voltages in response to a data control signal provided from the timing controller.

The above information disclosed in this Background section is only for enhancement of understanding of the background and therefore the information discussed in this Background section does not necessarily constitute prior art.

### SUMMARY

Aspects of some embodiments of the present disclosure relate to a display device, and for example, to a display device including an electrostatic discharge protection circuit.

Aspects of some embodiments of the present disclosure include a display device with relatively reduced failure of an electrostatic discharge protection circuit.

According to some embodiments of the present disclosure, a display device includes: a plurality of pixels in a display area, a data line electrically connected to a corresponding pixel among the plurality of pixels and overlapping with the display area and a non-display area adjacent to the display area, a scan line electrically connected to the corresponding pixel and overlapping with the display area and the non-display area, a scan driver in the non-display area and electrically connected to the scan lines, electrostatic discharge protection circuit in the non-display area and electrically connected to the data line, a first voltage line in the non-display area, configured to receive a first voltage and electrically connected to the scan driver and the electrostatic discharge protection circuit, and a second voltage line in the non-display area, configured to receive a second voltage different from the first voltage, and electrically connected to the scan driver and the electrostatic discharge protection circuit. According to some embodiments, the first voltage line may cross with the second voltage line, any one of the first voltage line and the second voltage line may include a line portion and a bridge electrode under the line portion and another of the first voltage line and the second voltage line in an area in which the first voltage line crosses with the second voltage line. According to some embodiments, the bridge electrode may be under an uppermost electrode constituting each one of the electrostatic discharge protection circuit.

According to some embodiments, one of the pixels may include a first transistor including a first semiconductor pattern and a first gate on the first semiconductor pattern, a second transistor including a second semiconductor pattern over the first gate and a second gate on the second semiconductor pattern, and a light-emitting element electrically connected to at least one of the first transistor or the second transistor.

According to some embodiments, the pixel may further include a first connection electrode connected to any one of a source area and a drain area of the first semiconductor pattern and over the second gate, and a second connection electrode connected to the first connection electrode and over the first connection electrode.

According to some embodiments, the bridge electrode may be under the first connection electrode.

According to some embodiments, the first semiconductor pattern may include silicon semiconductor, and the second semiconductor pattern may include a metal oxide semiconductor.

According to some embodiments, the electrostatic discharge protection circuit may include at least one first diode transistor diode-connected between the first voltage line and the data line, and at least one second diode transistor diode-connected between the data line and the second voltage line.

According to some embodiments, the at least one transistor may include a semiconductor pattern and a gate on the semiconductor pattern.

According to some embodiments, the bridge electrode may be on the same layer as the gate.

According to some embodiments, the electrostatic discharge protection circuit may further include a connection electrode over the gate and electrically connecting the gate and any one of a source area and a drain area of the semiconductor pattern.

According to some embodiments, the connection electrode may be on the same layer as the another of the first voltage line and the second voltage line.

According to some embodiments, a plurality of pads electrically connected to the first voltage line and the second voltage line may be further included. According to some embodiments, the display area may be between the plurality of pads and the electrostatic discharge protection circuit in a first direction.

According to some embodiments of the present disclosure, a display device includes: a pixel, a data line electrically connected to the pixel, a scan line electrically connected to the pixel, a scan driver electrically connected to the scan line, an electrostatic discharge protection circuit electrically connected to the data line, and a first line electrically connected to the scan driver and the electrostatic discharge protection circuit and configured to receive a first voltage. According to some embodiments, the first line may cross with a second line, and the first line may include a line portion and a bridge electrode under the line portion, and the bridge electrode may be under an uppermost electrode constituting the electrostatic protection circuit, and the line portion may be under or on the same layer as the uppermost electrode constituting the electrostatic discharge protection circuit.

According to some embodiments, the second line may receive a second voltage different from the first voltage and be electrically connected to the scan driver and the electrostatic discharge protection circuit.

According to some embodiments, the electrostatic discharge protection circuit may include at least one transistor diode-connected between the data line and the first line or the second line.

According to some embodiments, the at least one transistor may include a semiconductor pattern and a gate on the semiconductor pattern. According to some embodiments, the bridge electrode may be on the same layer as the gate.

According to some embodiments, the electrostatic discharge protection circuit may further include a connection electrode over the gate and electrically connecting the gate and any one of a source area and a drain area of the semiconductor pattern.

According to some embodiments, the uppermost electrode may comprise the connection electrode.

According to some embodiments, the connection electrode may be on the same layer as one of the first line and the second line.

According to some embodiments, the line portion may be on the same layer as one of the first line and the second line.

According to some embodiments, one of the first line and the second line, the line portion, and the uppermost electrode may be on the same layer.

According to some embodiments, a pad electrically connected to the first line may be further included. According to some embodiments, the pixel may be between the pad and the electrostatic discharge protection circuit in a first direction.

### BRIEF DESCRIPTION OF THE DRAWINGS

The accompanying drawings are included to provide a further understanding of embodiments according to the present disclosure, and are incorporated in and constitute a part of this specification. The drawings illustrate aspects of some embodiments of the present disclosure and, together with the description, serve to explain aspects of some embodiments of the present disclosure. In the drawings:

FIG. 1 is a perspective view of a display device according to some embodiments of the present disclosure;

FIG. 2 is a cross-sectional view of a display device according to some embodiments of the present disclosure;

FIG. 3 illustrates a plan view of a display device according to some embodiments of the present disclosure;

FIG. 4 is a cross-sectional view of a display device according to some embodiments of the present disclosure;

FIG. 5 is an enlarged plan view of a portion of a display device according to some embodiments of the present disclosure;

FIG. 6 is a cross-sectional view of a diode transistor according to some embodiments of the present disclosure;

FIG. 7A is an enlarged plan view of a cross area of voltage lines according to some embodiments of the present disclosure;

FIG. 7B is a cross-sectional view corresponding to a line I-I′ of FIG. 7A;

FIG. 8 illustrates a failure occurrence mechanism of an electrostatic discharge protection circuit; and

FIG. 9 is an enlarged plan view of a cross area of voltage lines according to some embodiments of the present disclosure.

### DETAILED DESCRIPTION

It will be understood that when an element or layer is referred to as being “on”, “connected to” or “coupled to” another element or layer, it can be directly on, connected or coupled to the other element or or intervening third elements may be present.

Like reference numerals in the drawings refer to like elements. In addition, in the drawings, the thickness and the ratio and the dimension of the element are exaggerated for effective description of the technical contents. The term “and/or” includes any and all combinations of one or more of the associated items.

Terms such as first, second, and the like may be used to describe various components, but these components should not be limited by the terms. Such terms are only used for distinguishing one element from other elements. For instance, a first component may be referred to as a second component, or similarly, a second component may be referred to as a first component, without departing from the scope of the present disclosure. The singular expressions include plural expressions unless the context clearly dictates otherwise.

In addition, the terms such as “under”, “lower”, “on”, and “upper” are used for explaining associations of items illustrated in the drawings. The terms are used as a relative concept and are described with reference to the direction indicated in the drawings.

It should be understood that the terms “comprise” or “have” are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which example embodiments belong. In addition, it will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, aspects of some embodiments of the present disclosure will be described in more detail with reference to the accompanying drawings.

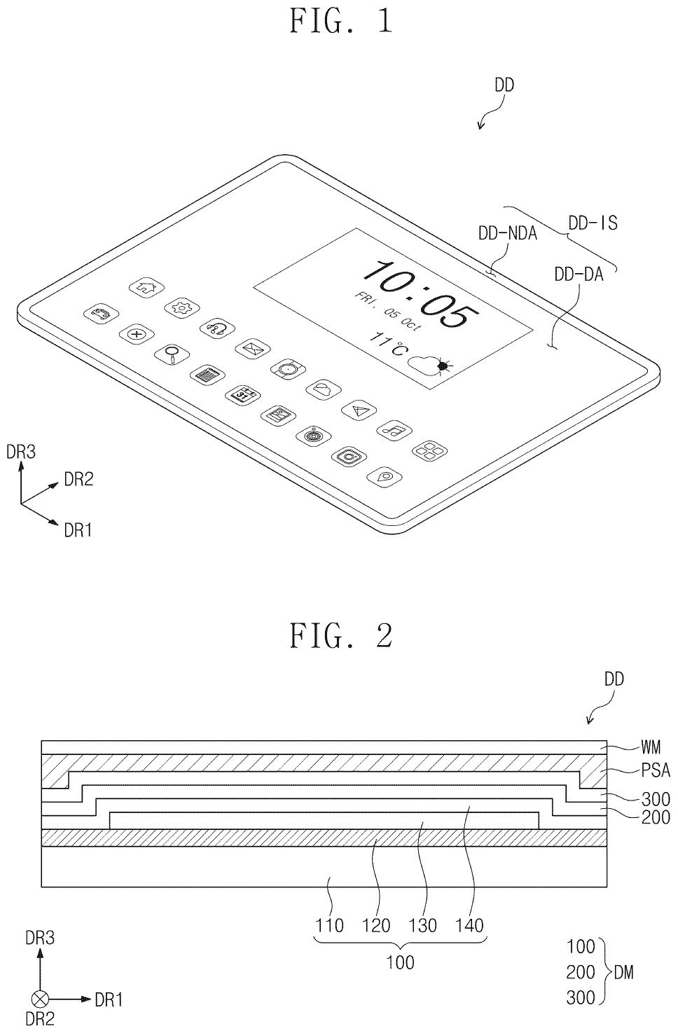

FIG. 1 is a perspective view of a display device DD according to some embodiments of the present disclosure. As shown in FIG. 1, the display device DD may display images through a display surface DD-IS. The display DD-IS is parallel to a surface defined by a first direction DR1 and a second direction DR2. A normal direction of the display surface DD-IS, namely, a thickness direction of the display device DD is indicated by a third direction DR3.

A front surface (or top surface) and a rear surface (or bottom surface) of each member or each unit to be described below are divided by the third direction DR3. However, the first to third direction DR1, DR2, and DR3 shown in the embodiments are merely examples.

According to some embodiments of the present disclosure, the display device DD is illustrated as including a planar display surface, but embodiments according to the present disclosure are not limited thereto. The display device DD may include a curved display surface or a stereoscopic display surface. The stereoscopic display surface may include a plurality of display areas indicating different directions, such as a bended display surface. The display device DD according to some embodiments may be a flexible display device DD. The flexible display device DD may be a foldable display device capable of being folded.

According to some embodiments, an example display device DD applicable to a tablet terminal is illustrated. The tablet terminal may be constituted of electronic modules mounted on a main board, a camera module, a power supply module or the like located in a bracket/case or the like together with the display device DD. The display device DD according to some embodiments of the present disclosure may be applied to a large electronic device such as a television or a monitor, or a small or medium electronic device such as a tablet, a vehicle navigator, a game player or a smart watch.

As illustrated in FIG. 1, the display surface DD-IS includes an image area DD-DA on which an image IM is displayed, and a bezel area DD-NDA adjacent to the image area DD-DA. The bezel area DD-NDA is an area at which images are not displayed. FIG. 1 shows icon images as an example image.

As shown in FIG. 1, the image area DD-DA may have a quadrangle shape (or a substantially quadrangle shape. The “substantially quadrangle shape” includes not only a quadrangle shape in a mathematical meaning, but also a quadrangle shape in which curved boundaries other than vertices are defined in vertex areas (or corner areas)).

The bezel area DD-NDA may surround the image area DD-DA. However, the embodiments are not limited thereto, and the shape of the bezel area DD-NDA may be deformed. For example, the bezel area DD-NDA may be located only in one side of the image area DD-DA.

FIG. 2 is a cross-sectional view of the display device DD according to some embodiments of the present disclosure.

The display device DD may include a display module DM and a window WM located on the display module DM. The display module DM and the window WM may be bonded by an adhesive layer PSA. According to some embodiments of the present disclosure, the window WM may be provided in a coating manner to contact the display module DM. Here, the adhesive layer PSA may be omitted.

The display module DM may include a display panel 100, an input sensor 200, and an anti-reflection layer 300. The display panel 100 may include a base layer 110, a driving element layer 120, a light-emitting element layer 130, and an encapsulation layer 140.

The driving element layer 120 may be located on the top surface of the base layer 110. The base layer 110 may be a flexible substrate that is bendable, foldable, rollable or the like. The base layer 110 may be a glass substrate, a metal substrate, or a polymer substrate. However, the embodiments of the present disclosure are not limited thereto, and the base layer 110 may be an inorganic layer, an organic layer, or a composite material layer. For example, the base layer 110 may have the same (or substantially the same) shape as the display panel 100.

The base layer 110 may have a multi-layer structure. For example, the base layer 110 may include a first synthetic resin layer, a second synthetic resin layer, and inorganic layers located therebetween. Each of the first and second synthetic resin layers may include a polyimide-based resin, but embodiments are not limited thereto.

The driving element layer 120 may be located on the base layer 110. The driving element layer 120 may include a plurality of insulation layers, a plurality of semiconductor patterns, a plurality of conductive patterns, signal lines, or the like. The driving element layer 120 may include a pixel driver.

The light-emitting element layer 130 may be located on the driving element layer 120. The light-emitting element layer 130 may include a light-emitting element. For example, the light-emitting element may include an organic light-emitting material, an inorganic light-emitting material, an organic-inorganic light-emitting material, quantum dots, quantum rods, micro-LEDs, or nano-LEDs.

The encapsulation layer 140 may be located on the light-emitting element layer 130. The encapsulation layer 140 may protect the light-emitting element layer 130, namely, the light-emitting elements, from a foreign matter such as moisture, oxygen or dust particles. The encapsulation layer 140 may include at least one inorganic encapsulation inorganic layer. The encapsulation layer 140 may include a laminate structure of a first inorganic encapsulation layer/an organic encapsulation layer/a second inorganic encapsulation layer.

The input sensor 200 may be directly located on the display panel 100. The input sensor 200 may detect a user input, for example, in an electromagnetic induction manner and/or an electrostatic capacitive manner. The display panel 100 and the input sensor 200 may be provided through continuous processes. Here, “to be directly located” may mean that a third component is not located between the input sensor 200 and the display panel 100. For example, a separate adhesive layer may not be located between the input sensor 200 and the display panel 100.

The anti-reflection layer 300 reduces a reflectance of external light incident from an upper side of the window WM. The anti-reflection layer 300 according to some embodiments of the present disclosure may include a phase retarder and a polarizer. The retarder may be a film type or a liquid crystal coating type, and include a λ/2 phase retarder and/or a λ/4 phase retarder. The polarizer may also be a film type or a liquid crystal coating type. The film type polarizer may include a stretched synthetic resin film, and the liquid crystal coating type polarizer may include liquid crystals arranged in a prescribed array. The phase retarder and the polarizer may further include protection films. The phase retarder and the polarizer themselves or the protection films thereof may be defined as the base layer of the anti-reflection layer 300.

The anti-reflection layer 300 according to some embodiments of the present disclosure may include color filters. The color filters have a prescribed array. An array of a plurality of group color filters divided by colors may be determined considering an array of a plurality of group pixels divided by emission colors. The anti-reflection layer 300 may further include a black matrix adjacent to the color filters. The anti-reflection layer 300 including the color filters may be directly located on the display panel 100.

The window WM according to some embodiments of the present disclosure may include a base layer and a light blocking pattern. The base layer may include a glass substrate and/or a synthetic resin film, etc. The light blocking pattern partially overlaps with the base layer. The light blocking pattern may be located on the rear surface of the base layer, and define (or substantially define) the bezel area DD-NDA (see FIG. 1) of the display device DD. An area without the light blocking pattern located therein may define the image area DD-DA (see FIG. 1) of the display device DD

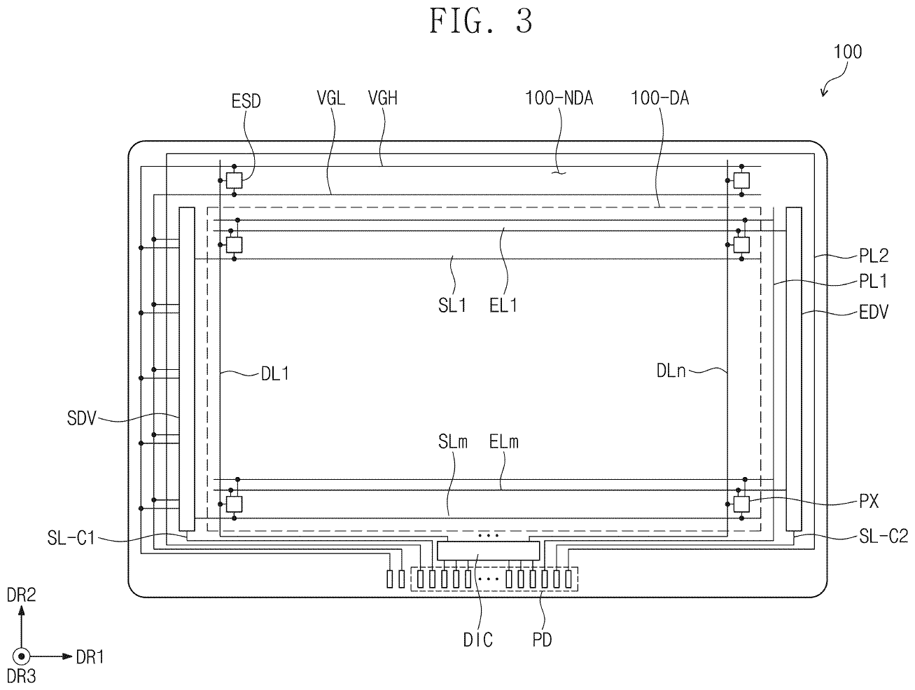

FIG. 3 is a plan view of the display panel 100 according to some embodiments of the present disclosure.

Referring to FIG. 3, the display panel 100 may include a plurality of pixels PX, a scan driver SDV, an emission driver EDV, a plurality of signal lines, electrostatic discharge protection circuits ESD, and a plurality of pads PD. The plurality of pixels PX are located in the display area 100-DA. A driving chip DIC mounted on the non-display area 100-NDA may include a data driver. The display area 100-DA is located between the electrostatic discharge protection circuits ESD and the pads PD in the second direction DR2.

The display area 100-DA may correspond to the image area DD-DA of FIG. 1, and the non-display area 100-NDA may correspond to the bezel area DD-NDA. “An area or portion correspond to an area or portion” in the specification means that they overlap with each other, and two different areas or portions are not necessarily limited to have the same shape and area. The data driver according to some embodiments may also be integrated into the display panel 100, like the scan driver SDV and the emission driver EDV.

The scan driver SDV may generate a plurality of scan signals, the driving chip DIC may generate a plurality of data voltages, and the emission driver EDV may generate a plurality of emission signals. The pixels PX may respectively receive the data voltages in response to the scan signals.

The plurality of signal lines may include a plurality of scan lines SL1 to SLm, a plurality of data lines DL1 to DLn, a plurality of emission lines EL1 to ELm, first and second control lines SL-C1 and SL-C2, first and second power lines PL1 and PL2, and first and second voltage lines VGH and VGL. Each of m and n is a natural number of 2 or greater.

The scan lines SL1 to SLm may overlap with the display area 100-DA and the non-display area 100-NDA, and extend in the first direction DR1 to be electrically connected to the pixels PX and the scan driver SDV. The scan lines SL1 to SLm are respectively connected to corresponding pixels among the pixels PX, for example, pixels arranged in the same pixel row.

The data lines DL1 to DLn may overlap with the display area 100-DA and the non-display area 100-NDA, and extend in the second direction DR2 to be electrically connected to the pixels PX and the driving chip DIC. The data lines DL1 to DLn are respectively connected to corresponding pixels among the pixels PX, for example, pixels arranged in the same pixel column.

According to some embodiments, one driving chip DIC is illustrated to drive the overall data lines DL1 to DLn of the display area 100-DA, but is not limited thereto. One of two driving chips DIC may drive data lines of group 1, and the other may drive data lines of group 2. The emission lines EL1 to ELm may extend in the first direction DR1 to be electrically connected to the pixels PX and the emission driver EDV.

The first power line PL1 may receive a first power supply voltage, and the second power line PL2 may receive a second power supply voltage having a lower level than the first power supply voltage. According to some embodiments, a second electrode (e.g., a cathode) of the light-emitting element is electrically connected to the second power line PL2.

The first control line SL-C1 may be connected to the scan driver SDV and extend towards a lower end of the display panel 100. The second control line SL-C2 may be connected to the emission driver EDV and extend to the lower end of the display panel 100. The pads PD may be located in the non-display area 100-NDA adjacent to the lower end of the display panel 100, and be more adjacent to the lower end of the display panel 100 than the driving chip DIC. The pads PD may be connected to the driving chip DIC and a portion of the signal lines. The portion of the signal lines described above are connected to corresponding pads among the plurality of pads PD.

A first voltage line VGH may receive a first voltage, and a second voltage line VGL may receive a second voltage having a lower level than the first voltage. For example, the first voltage may be a positive (+) constant voltage, and the second voltage may be a negative (−) constant voltage. The first voltage line VGH and the second voltage line VGL are electrically connected to the scan driver SDV and the electrostatic discharge protection circuits ESD.

The scan driver SDV generates a scan signal using a first voltage received from the first voltage line VGH and a second voltage received from the second voltage line VGL. Each of the electrostatic discharge protection circuits ESD may be located corresponding to one of the plurality of data lines DL1 to DLn, and be electrically connected thereto. The electrostatic discharge protection circuit ESD discharges the static electricity to the first voltage line VGH when positive (+) static electricity is generated in the corresponding data line, and to the second voltage line VGL when negative (−) static electricity is generated in the corresponding data line.

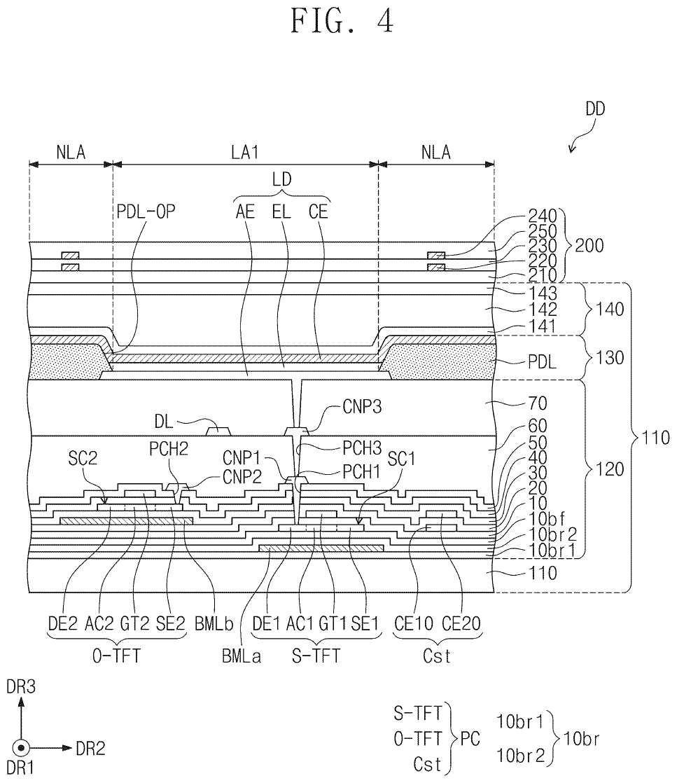

FIG. 4 is a cross-sectional view of the display device DD according to some embodiments of the present disclosure.

In FIG. 4, a cross section of an area corresponding to one pixel PX of FIG. 3 is shown. In FIG. 4, some components, for example, the anti-reflection layer 300 to the window WM of the display device DD of FIG. 2 are not illustrated for ease of illustration.

The pixel driving circuit PC configured to drive the light-emitting element LD may include a plurality of pixel driving elements. The pixel driving circuit PC may include a plurality of transistors S-TFT and O-TFT, and a capacitor Cst. In FIG. 4, a silicon transistor S-TFT (or a first transistor) and an oxide transistor O-TFT (or a second transistor) are illustrated as an example. The pixel driving circuit PC of FIG. 4 is merely an example and the configuration of the pixel driving circuit PC is not necessarily limited thereto. The pixel driving circuit PC may also include only one-type transistors between the silicon transistor S-TFT and the oxide transistor O-TFT.

Referring to FIG. 4, the base layer 110 is shown as a single layer. The base layer 110 may include a synthetic resin such as polyimide. The base layer 110 may be provided by coating a synthetic resin layer on a work substrate (or a carrier substrate). When subsequent processes are performed to complete the display module DM, the work substrate may be removed. The base layer 110 according to some embodiments of the present disclosure may also have a multilayer structure including a first synthetic resin layer, at least one inorganic layer, and a second synthetic resin layer.

Referring to FIG. 4, a barrier layer 10br may be located on the base layer 110. The barrier layer 10br prevents or reduces instances of foreign matter or contaminants entering from the outside. The barrier layer 10br may include at least one inorganic layer. The barrier layer 10br may include a silicon oxide layer and a silicon nitride layer. Each of them may be provided in plural, and the silicon oxide layers and the silicon nitride layers may be alternately laminated.

The barrier layer 10br may include a lower barrier layer 10br1 and an upper barrier layer 10br2. A first shield electrode BMLa may be located between the lower barrier layer 10br1 and the upper barrier layer 10br2. The first shield electrode BMLa may be arranged corresponding to the silicon transistor S-TFT. The first shield electrode BMLa may include a metal, for example, molybdenum. The first shield electrode BMLa may receive a bias voltage.

A buffer layer 10bf may be located on the barrier layer 10br. The buffer layer 10bf may prevent or reduce instances of a phenomenon in which metal atoms or impurities diffuse to an upper first semiconductor pattern SC1 from the base layer 110. The buffer layer 10bf may include at least one inorganic layer. The buffer layer 10bf may include a silicon oxide layer or a silicon nitride layer.

The first semiconductor pattern SC1 may be located on the buffer layer 10bf. The first semiconductor pattern SC1 may include a silicon semiconductor. For example, the silicon semiconductor may include amorphous silicon, polycrystalline, or the like. For example, the first semiconductor pattern SC1 may include low temperature polysilicon.

The first semiconductor pattern SC1 may have different electrical properties according to whether it is doped. The first semiconductor pattern SC1 may include a first area with a high conductivity and a second area with a low conductivity. The first area may be doped with an N-type dopant or a P-type dopant. The second area may be a non-doped area, or be doped at a low concentration compared to the first area. A source area SE1 (hereinafter a first source area), a channel area AC1 (or an active area, hereinafter a first channel area), and a drain area DE1 (hereinafter a first drain area) of the silicon transistor S-TFT may be provided from the first semiconductor pattern SC1. The source area SE1 and the drain area DE1 may extend in opposite directions from the first channel area AC1 in a cross-sectional view.

The first insulation layer 10 may be located on the buffer layer 10bf. The first insulation layer 10 may cover the first semiconductor pattern SC1. The first insulation layer 10 may be an inorganic layer. Not only the first insulation layer 10 but also the inorganic layer of the circuit element layer 120 to be described below may have a single layer or multilayer structure and include at least one of the foregoing materials, but embodiments according to the present disclosure are not limited thereto.

A gate GT1 (hereinafter a first gate) of the silicon transistor S-TFT is located on the first insulation layer 10. The first gate GT1 may be a portion of a metal pattern. The first gate GT1 may overlap with the first active area AC1. The first gate GT1 may be a mask in a process for doping the first semiconductor pattern SC1. A first electrode CE10 of the storage capacitor Cst is located on the first insulation layer 10. In a plan view, the first electrode CE10 and the first gate GT1 may have an integral shape.

A second insulation layer 20 may be located on the first insulation layer 10 and cover the first gate GT1. According to some embodiments of the present disclosure, an upper electrode overlapping with the gate GT1 may be further located on the second insulation layer 20. A second electrode CE20 overlapping with the first electrode CE10 may be located on the second insulation layer 20. The upper electrode and the second electrode CE20 may have an integral shape in a plan view.

A second shield electrode BMLb is located on the second insulation layer 20. The second shield electrode BMLa may be arranged corresponding to the oxide transistor O-TFT. According to some embodiments of the present disclosure, the second shield electrode BMLb may be omitted. A third insulation layer 30 may be located on the second insulation layer 20. The second semiconductor pattern SC2 may be located on the third insulation layer 30. The second semiconductor pattern SC2 may include a channel area AC2 (hereinafter a second channel area) of the oxide transistor O-TFT. The second semiconductor pattern SC2 may include a metal-oxide semiconductor. The second semiconductor pattern SC2 may include a transparent conductive oxide (TCO) such as indium tin oxide (ITO), indium zinc oxide (IZO), indium-gallium-zinc oxide (IGZO), zinc oxide (ZnOx) or indium oxide (In2O3).

The metal-oxide semiconductor may include a plurality of areas SE2, AC2, and DE2 divided according to whether a TCO is reduced. An area in which the TCO is reduced (hereinafter, a reduction area) has a high conductivity compared to an area in which the metal oxide is not reduced (hereinafter, a non-reduction area). The reduction area may substantially serve as a source/drain or a signal line of the transistor. The non-reduction area substantially corresponds to a semiconductor region (or channel) of a transistor. A fourth insulation layer 40 may be located on the third insulation layer 30. As shown in FIG. 4, the fourth insulation layer 40 may cover the second semiconductor pattern SC2.

A gate GT2 (hereinafter a second gate) of the oxide transistor O-TFT is located on the fourth insulation layer 40. The second gate GT2 of the oxide transistor O-TFT may be a portion of a metal pattern. The second gate GT2 of the oxide transistor O-TFT overlaps with the second channel area AC2. A fifth insulation layer 50 may be located on the fourth insulation layer 40 and cover the second gate GT2. Each of the first to fifth insulation layers 10 to 50 may be an inorganic layer.

A first connection pattern CNP1 and a second connection pattern CNP2 may be located on the fifth insulation layer 50. The first connection pattern CNP1 and the second connection pattern CNP2 may be provided through the same processes, and thus may have the same materials and laminate structure. The first connection pattern CNP1 may be connected to any one of the first source area SE1 and the drain area DE1 of the silicon transistor S-TFT through a first pixel contact hole PCH1 penetrating through the first to fifth insulation layers 10, 20, 30, 40, and 50. According to some embodiments, the connection electrode CNP1 may be connected to the first drain area DE1 in the p-type silicon transistor S-TFT. The second connection pattern CNP2 may be connected to the source area SE2 of the oxide transistor O-TFT through a second pixel contact hole PCH2 penetrating through the fourth and fifth insulation layers 40 and 50. The connection relation of the first connection pattern CNP1 and the second connection pattern CNP2 to the silicon transistor S-TFT and the oxide transistor O-TFT is not necessarily limited thereto.

A sixth insulation layer 60 may be located on the fifth insulation layer 50. A third connection pattern CNP3 may be located on the sixth insulation layer 60. The third connection electrode CNP3 may be connected to the first connection electrode CNP1 through a third pixel contact hole PCH3 penetrating through the sixth insulation layer 60. A corresponding data line DL may be located on the sixth insulation layer 60. A seventh insulation layer 70 may be located on the sixth insulation layer 60 and cover the third connection electrode CNP3 and the data line DL. The third connection pattern CNP3 and the data line DL are provided through the same processes, and thus may have the same materials and laminate structure. Each of the sixth and seventh insulation layers 60 and 70 may be an organic layer.

The light-emitting element LD may be electrically connected to at least one of the plurality of transistors S-TFT or O-TFT. According to some embodiments, an example light-emitting element LD is illustrated as being electrically connected to the silicon transistor S-TFT.

The light-emitting element LD may include an anode AE (or a first electrode), a light emitting layer EL, and a cathode CE (or a second electrode). The anode AE1 of the light-emitting element LD may be located on the seventh insulation layer 70. The anode AE may be a (semi-) transmissive electrode or a reflective electrode. The anode AE may include a laminate structure in which ITO/Ag/ITO are sequentially laminated. The positions of the anode AE and the cathode CE may be exchanged with each other.

A pixel definition layer PDL may be located on the seventh insulation layer 70. The pixel definition layer PDL may be an organic layer. The pixel definition layer PDL may have light absorption property and have a block color. For example, the pixel definition layer PDL may include a black coloring agent. The black coloring agent may include a block dye or a black pigment. The block coloring agent may include a metal like chromium, an oxide thereof, or a carbon black. The pixel definition layer PDL may correspond to a light blocking pattern having light blocking property.

The pixel definition layer PDL may cover a portion of the anode AE. For example, an opening PDL-OP configured to expose a portion of the anode AE may be defined in the pixel definition layer PDL. The emission area LA1 may be defined to correspond to the opening PDL-OP. The emission area LA1 may be surrounded by the non-emission area NLA.

According to some embodiments of the present disclosure, a hole control layer may be located between the anode AE and the light-emitting layer EL. The hole control layer may include a hole transport layer and further include a hole injection layer. An electron control layer may be located between the light-emitting layer EL and the cathode CE. The electron control layer may include an electron transport layer and further include an electron injection layer.

The encapsulation layer 140 may cover the light-emitting element LD. The encapsulation layer 140 may include an inorganic encapsulation layer 141, an organic encapsulation layer 142, and an inorganic encapsulation layer 143 that are sequentially laminated, but the layers constituting the encapsulation layer 140 are not necessarily limited thereto. Each of the inorganic encapsulation layers 141 and 143 may include a silicon nitride layer, a silicon oxynitride layer, a silicon oxide layer, a titanium oxide layer, an aluminum oxide layer or the like. Each of the inorganic encapsulation layers 141 and 143 may have a multilayer structure. The organic encapsulation layer 142 may include an acrylic-based organic layer, but is not limited thereto.

The input sensor 200 according to some embodiments may include at least one conductive layer (or at least one sensor conductive layer) and at least one insulation layer (or at least one sensor insulation layer). The input sensor 200 according to some embodiments may include a first insulation layer 210 (or a first sensor insulation layer), a first conductive layer 220 (or a first sensor conductive layer), a second insulation layer 230 (or a second sensor insulation layer) and a third insulation layer 250 (or a third sensor insulation layer). In FIG. 4, a line component of the first conductive layer 220 and a line component of the second conductive layer 240 are briefly illustrated.

The first insulation layer 210 may be directly located on the display panel 100. The first insulation layer 210 may be an inorganic layer including any one among silicon nitride, silicon oxynitride, or silicon oxide. Each of the first conductive layer 220 and the second conductive layer 240 may have a single layer structure or a multilayer structure laminated along the third direction DR3. The first conductive layer 220 and the second conductive layer 240 may include line components defining a mesh-shaped electrode. The line component of the first conductive layer 220 may be connected or not to the line component of the second conductive layer 240 through a contact hole penetrating the second insulation layer 230 according to the positions thereof.

Each of the first conductive layer 220 and the second conductive layer 240 of single layer structures may include a metal layer or a TCO layer. The metal layer may include molybdenum, silver, titanium, copper, aluminum, or an alloy thereof. The transparent conductive layer may include a TCO such as indium tin oxide (ITO), Indium zinc oxide (IZO), zinc oxide (ZnOx), or indium-zinc-tin oxide (IZTO). Besides, the transparent conductive layer may include a metal nano-wire, graphene or a conductive polymer such as PEDOT.

Each of the first conductive layer 220 and the second conductive layer 240 of multilayer structures may include metal layers. The conductive layer of the multilayer structure may include at least one metal layer and at least one transparent conductive layer. The second insulation layer 230 may be located between the first conductive layer 220 and the second conductive layer 240. The third insulation layer 250 may cover the second conductive layer 240. According to some embodiments of the present disclosure, the third insulation layer 250 may be omitted. Each of the second insulation layer 230 and the third insulation layer 250 may include an inorganic layer or an organic layer.

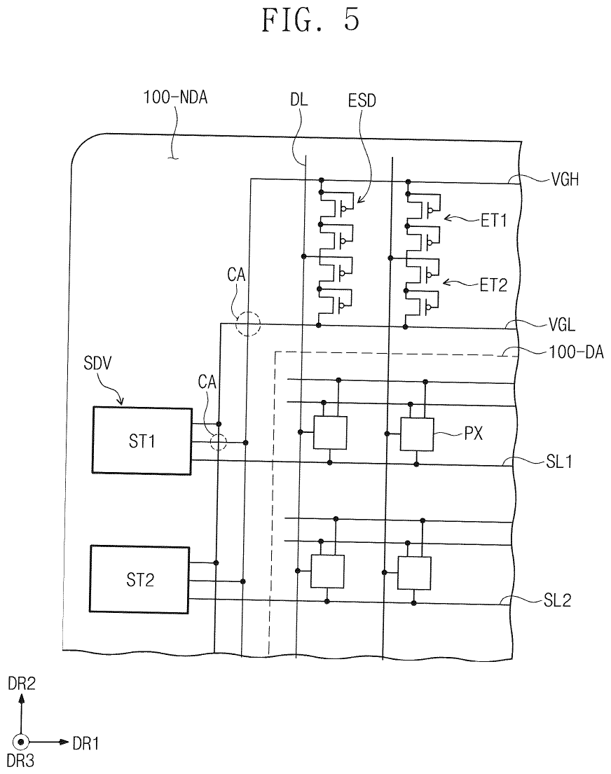

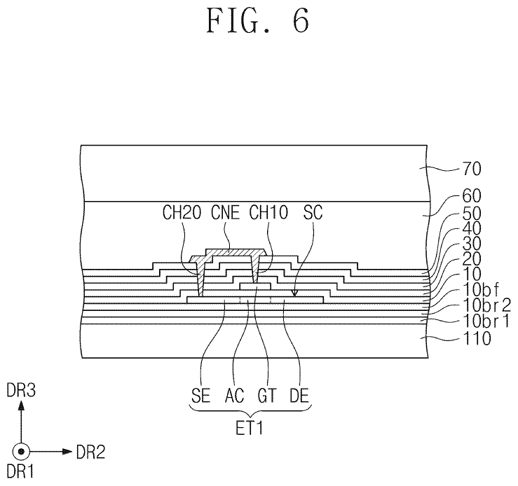

FIG. 5 is an enlarged plan view of a portion of the display device DD according to some embodiments of the present disclosure. FIG. 6 is a cross-sectional view of a diode transistor ET1 according to some embodiments of the present disclosure.

Referring to FIG. 5, the scan driver SDV may include a plurality of stage circuits. For example, the scan driver SDV may include m stage circuits corresponding one-to-one to the m scan lines SL1 to SLm shown in FIG. 3. The plurality of stage circuits may have the same circuit configuration. FIG. 5 illustrates first and second example stage circuits ST1 and ST2 connected to the first and second scan lines SL1 and SL2, respectively.

The first and second stage circuits ST1 and ST2 may output scan signals corresponding to the first and second scan lines SL1 and SL2. The first and second stage circuits ST1 and ST2 may receive the first voltage from the first voltage line VGH, receive the second voltage from the second voltage line VGL, and receive a clock signal from a signal line in order to generate the scan signals. The plurality of stage circuits may also receive signals output from adjacent stage circuits.

Each one of the electrostatic discharge protection circuits ESD is connected to corresponding one of the plurality of data lines DL. The electrostatic discharge protection circuit ESD may include at least one transistor diode-connected between the data line DL and one of the first voltage line VGH or second voltage line VGL. According to some embodiments, an example electrostatic discharge protection circuit ESD including two types of transistors is shown.

The electrostatic discharge protection circuit ESD may include at least one first diode transistor ET1 diode-connected between the first voltage line VGH and the data line DL. According to some embodiments, two example first diode transistors ET1 connected in series are shown. The electrostatic discharge protection circuit ESD may include at least one second diode transistor ET2 diode-connected between the second voltage line VGL and the data line DL. According to some embodiments, two example second diode transistors ET2 connected in series are shown.

When static electricity flows into the data line DL, positive (+) static electricity is guided to the first voltage line VGH, and negative (−) static electricity is guided to the second voltage line VGL to prevent or reduce damage to the pixels connected to the data line DL.

According to some embodiments, example p-type diode transistors ET1 and ET2 are illustrated, but the electrostatic discharge protection circuit ESD may include n-type diode transistors or both the p-type and n-type diode transistors. The gates of the p-type diode transistors are connected to terminals connected to the first voltage line VGH or the second voltage line VGL between both terminals of the p-type diode transistors, but the gates of the n-type diode transistors are connected to opposite terminals to terminals connected to the first voltage line VGH or the second voltage line VGL between both terminals of the n-type diode transistors.

FIG. 6 illustrates a cross section of one first diode transistor ET1 as an example diode transistor. A laminate structure of the second diode transistor ET2 may be substantially the same as that of the second conductive layer ET1.

The first diode transistor ET1 may include a semiconductor pattern SC located on the buffer layer 10bf and a gate GT located on the semiconductor pattern SC. The semiconductor pattern SC may include a source area SE, a channel area AC (or an active area), and a drain area DE. The source area SE and the drain area DE may extend in opposite directions from each other from the channel region AC in a cross-sectional view. The source area SE and the drain area DE of the semiconductor pattern SC correspond to both the terminals of the first diode transistor ET1.

The semiconductor pattern SC may include a silicon semiconductor and include the same materials as and be provided in the same processes as the first semiconductor pattern SC1 of FIG. 4. The semiconductor pattern SC according to some embodiments of the present disclosure may include a metal oxide semiconductor, and include the same materials as and be provided in the same processes as the first semiconductor pattern SC2 of FIG. 4.

The gate GT may be located on the same layer as, include the same materials as, and be provided in the same processes as the first gate GT1 of FIG. 4. The gate GT according to some embodiments of the present disclosure may include the same materials as and be provided in the same processes as the second shield electrode BMLb of FIG. 4.

The first diode transistor ET1 may electrically connect the gate GT and one of the source area SE and drain area DE of the semiconductor pattern SE, and further include a connection electrode CNE located on the gate GT. The connection electrode CNE may be located on the same layer as, include the same materials as, and be provided in the same processes as the first connection electrode CNP1 of FIG. 4. The connection electrode CNE according to some embodiments may be connected to the gate GT through the first contact hole CH10, and connected to the source area SE through the second contact hole CH20. The first contact hole CH10 may penetrate through the second to fifth insulation layers 20 to 50, and the second contact hole CH 20 may penetrate through the first to fifth insulation layers 10 to 50.

The connection electrode CNE of the first diode transistor ET1 may corresponds to, namely, an uppermost electrode constituting the electrostatic discharge protection circuit ESD. The “uppermost electrode” means that it is provided at the latest time in a manufacturing process of the electrostatic discharge protection circuit ESD. The first diode transistor ET1 may normally perform functions only if the gate GT and the source area SE are electrically connected by the connection electrode CNE.

A sixth insulation layer 60 and a seventh insulation layer 70 may be located on the connection electrode CNE. According to some embodiments, at least one of the encapsulation layer 140, the first insulation layer 210, the second insulation layer 230, or the third insulation layer 250 of FIG. 4 may be further located on the connection electrode CNE.

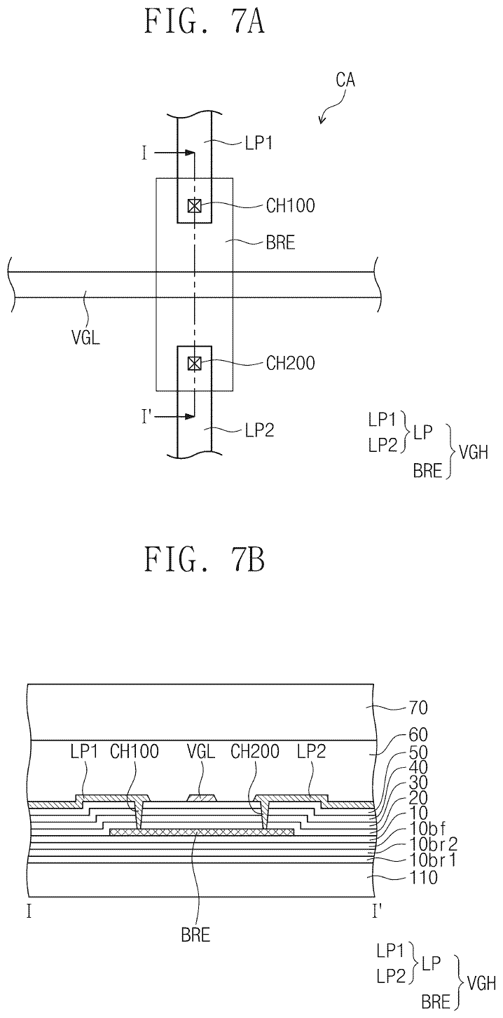

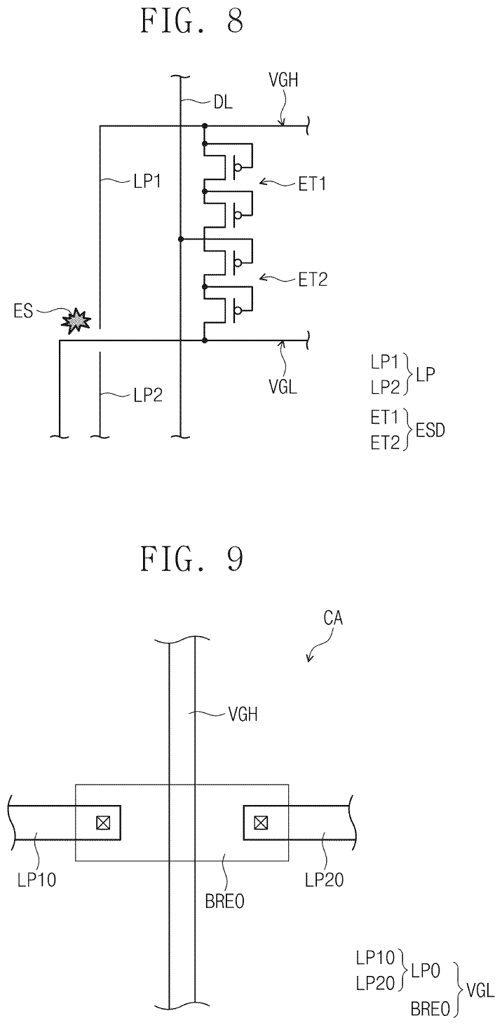

FIG. 7A is an enlarged plan view of a cross area CA of the voltage lines VGH and VGL according to some embodiments of the present disclosure. FIG. 7B is a cross-sectional view corresponding to a line I-P′ of FIG. 7A. FIG. 8 illustrates a failure occurrence mechanism of the electrostatic discharge protection circuit ESD.

As described above with reference to FIGS. 3 and 5, since the first voltage line VGH and the second voltage line VGL extend from the pads PD to an area in which the electrostatic discharge protection circuits ESD are located in the non-display area 100-NDA, and are connected to the scan driver SDV at a plurality of points, a plurality of cross areas CA may be provided between the first voltage line VGH and the second voltage line VGL.

In order to insulate the first voltage line VGH and the second voltage line VGL from each other in the cross area CA, one of the two lines includes a bridge electrode BRE located on a different layer from the other. One of the first voltage line VGH and the second voltage line VGL is located on a different layer from the bridge electrode BRE, and includes a line portion (LP) located on the same layer as the other.

The line portion LP includes a first line portion LP1 and a second line portion LP2 spaced apart from each other, and the bridge electrode BRE is located on the different layer from the line portion LP to electrically connect the first line portion LP1 and the second line portion LP2. Accordingly, the bridge electrode BRE crosses with the other between the first voltage line VGH and the second voltage line VGL in the cross area CA.

As shown in FIGS. 7A and 7B, the first voltage line VGH may include the line portion LP and the bridge electrode BRE. The bridge electrode BRE may be located under the line portion LP. In addition, the bridge electrode BRE may be located under the line portion VGL.

The bridge electrode BRE according to some embodiments may be located on the same layer as, include the same materials as, and be provided in the same processes as the first gate GT1 of FIG. 4 and the gate GT of FIG. 6. The line portion LP may be located on the same layer as, include the same materials as, and be provided in the same processes as the first connection electrode CNP1 of FIG. 4. The line portion LP and the second voltage line VGL may be located on the same layer, include the same materials, and be provided in the same processes. According to some embodiments, the line portion LP of the first voltage line VGH, and the second voltage line VGL are provided in the same processes as the first connection electrode CNP1 of FIG. 4, and thus the bridge electrode BRE is located under the first connection electrode CNP1.

The first line portion LP1 may be connected to the bridge electrode BRE through the first contact hole CH100, and the second line portion LP2 may be connected to the bridge electrode BRE through the second contact hole CH200. The first contact hole CH100 and the second contact hole CH200 may penetrate through the first to fifth insulation layers 10 to 50.

Consequently, the bridge electrode BRE according to some embodiments is located under the line portion LP and the second voltage line VGL. In other words, the bridge electrode BRE is provided earlier than the line portion LP and the second voltage line VGL, and the line portion LP and the second voltage line VGL are provided in the same processes.

The bridge electrode BRE is located under the connection electrode CNE that is the uppermost electrode constituting the electrostatic discharge protection circuit ESD described referring to FIG. 6. Providing the bridge electrode BRE earlier than the completion of the electrostatic discharge protection circuit ESD is for providing the first voltage line VGH and the second voltage line VGL earlier than or concurrently with the completion of the electrostatic discharge protection circuit ESD. Accordingly, the electrostatic discharge protection circuit ESD may be suppressed from being damaged by static electricity generated in the display device manufacturing process.

FIG. 8 illustrates a mechanism in which the electrostatic discharge protection circuit ESD is damaged when the bridge electrode BRE is provided later than the line portion LP and the second voltage line VGL.

Referring to FIGS. 6, 7B, and 8, when the bridge electrode BRE is provided over the line portion LP and the second voltage line VGL, it may be assumed that except the bridge electrode BRE, the remaining component of the first voltage line VGH, the second voltage line VGL, and the electrostatic discharge protection circuit ESD are completed. When the bridge electrode BRE is provided over the line portion LP and the second voltage line VGL, the bridge electrode BRE may be provided in the same processes as, for example, the third connection electrode CNP3 of FIG. 4.

When static electricity ES generated in a process for providing the third connection electrode CNP3 is flowed in through the first line portion LP1, the static electricity ES is flowed into the first diode transistor ET1 to damage the same. Accordingly, the first voltage line VGH is short-circuited to the data line DL to cause a black line failure to pixels connected to the data line DL.

However, as described above with reference to FIGS. 5 to 7, when the bridge electrode BRE is provided earlier than the line portion LP, and the first voltage line VGH and the second voltage line VGL are provided earlier than or concurrently with the completion of the electrostatic discharge protection circuit ESD, static electricity generated in subsequent processes may be dispersed through the scan driver SDV connected electrically to the first voltage line VGH and the second voltage line VGL. Accordingly, damage to the electrostatic discharge protection circuit ESD by the static electricity generated in the display device manufacturing process may be prevented or reduced.

FIG. 9 is an enlarged plan view of a cross area of the voltage lines VGH and VGL according to some embodiments of the present disclosure.

According to the embodiments shown in FIG. 9, unlike the embodiments shown in FIGS. 7A and 7B, the second voltage line VGL may include a line portion LP0 and a bridge electrode BRE0. The bridge electrode BRE0 may be located under the line portion LP0. In addition, the bridge electrode BRE0 may be located under the first voltage line VGH.

As described above with reference to FIGS. 7A to 8, even though generated in the display device manufacturing process, the static electricity is dispersed through the scan driver SDV and thus the second diode transistor ET2 of FIG. 5 may be suppressed from being damaged.

In FIGS. 5 to 9, the first voltage line VGH and the second voltage line VGL are described as an example first line and second line crossing with each other, but embodiments according to the present disclosure may also be applied to a case where one of the first voltage line VGH and the second voltage line VGL is the first line and the other is the second line. The other signal line may receive a clock signal or a power supply voltage.

In case where the first line crosses with the second line and when the first line, one of the first voltage line VGH and the second voltage line VGL, includes the bridge electrode, the bridge electrode BRE as described above may be located under the uppermost electrode constituting the electrostatic discharge protection circuit ESD. When the first line, one of the first voltage line VGH and the second voltage line VGL, does not include the bridge electrode BRE, the first line as described above may be located under or on the same layer as the uppermost electrode constituting the electrostatic discharge protection circuit ESD.

According to some embodiments of the present disclosure, the voltage lines configured to provide voltages to the scan driver and the electrostatic discharge protection circuit are completed in the same processes as the electrostatic discharge protection circuit or provided earlier than the electrostatic discharge protection circuit. Accordingly, even when generated in the display device manufacturing process, the static electricity may be dispersed through the scan driver and thus suppress damages of the electrostatic discharge protection circuit.

While aspects of some embodiments of the present disclosure have been described with reference to aspects of some embodiments thereof, it will be clear to those of ordinary skill in the art to which the invention pertains that various changes and modifications may be made to the described embodiments without departing from the spirit and technical area of the invention as defined in the appended claims and their equivalents.

Thus, the scope of embodiments according to the present disclosure shall not be restricted or limited by the foregoing description, but be determined by the broadest permissible interpretation of the following claims, and their equivalents.

1. A display device comprising:
a plurality of pixels in a display area;
a data line electrically connected to a corresponding pixel among the plurality of pixels and overlapping with the display area and a non-display area adjacent to the display area;
a scan line electrically connected to the corresponding pixel and overlapping with the display area and the non-display area;
a scan driver in the non-display area and electrically connected to the scan line;
an electrostatic discharge protection circuit in the non-display area and electrically connected to the data line;
a first voltage line in the non-display area, configured to receive a first voltage and electrically connected to the scan driver line and the electrostatic discharge protection circuit; and
a second voltage line in the non-display area, configured to receive a second voltage different from the first voltage, and electrically connected to the scan driver line and the electrostatic discharge protection circuit,
wherein the first voltage line crosses with the second voltage line,
any one of the first voltage line and the second voltage line comprises a line portion and a bridge electrode under the line portion and another of the first voltage line and the second voltage line in an area in which the first voltage line crosses with the second voltage line, and
the bridge electrode is under an uppermost electrode constituting the electrostatic discharge protection circuit.

2. The display device of claim 1, wherein the corresponding pixel comprises:
a first transistor comprising a first semiconductor pattern and a first gate on the first semiconductor pattern;
a second transistor comprising a second semiconductor pattern over the first gate and a second gate on the second semiconductor pattern; and
a light-emitting element electrically connected to at least one of the first transistor or the second transistor.

3. The display device of claim 2, wherein the corresponding pixel further comprises:
a first connection electrode connected to any one of a source area and a drain area of the first semiconductor pattern and over the second gate; and
a second connection electrode connected to the first connection electrode and over the first connection electrode.

4. The display device of claim 3, wherein the bridge electrode is under the first connection electrode.

5. The display device of claim 2, wherein the first semiconductor pattern comprises silicon semiconductor, and the second semiconductor pattern comprises a metal oxide semiconductor.

6. The display device of claim 1, wherein the electrostatic discharge protection circuit comprises:
at least one first diode transistor diode-connected between the first voltage line and the data line; and
at least one second diode transistor diode-connected between the data line and the second voltage line.

7. The display device of claim 6, wherein
the at least one first diode transistor comprises a semiconductor pattern and a gate on the semiconductor pattern, and
the bridge electrode is on a same layer as the gate.

8. The display device of claim 7, wherein the electrostatic discharge protection circuit further comprises a connection electrode over the gate and electrically connecting the gate and any one of a source area and a drain area of the semiconductor pattern.

9. The display device of claim 8, wherein the connection electrode is on a same layer as the another of the first voltage line and the second voltage line.

10. The display device of claim 1, further comprising:
a plurality of pads electrically connected to the first voltage line and the second voltage line,
wherein the display area is between the plurality of pads and the electrostatic discharge protection circuit in a first direction.

11. A display device comprising:
a pixel;
a data line electrically connected to the pixel;
a scan line electrically connected to the pixel;
a scan driver electrically connected to the scan line;
an electrostatic discharge protection circuit electrically connected to the data line; and
a first line electrically connected to the scan driver and the electrostatic discharge protection circuit and configured to receive a first voltage,
wherein the first line crosses with a second line, and the first line comprises a line portion and a bridge electrode under the line portion,
wherein the bridge electrode is under an uppermost electrode constituting the electrostatic discharge protection circuit, and the line portion is under or on a same layer as the uppermost electrode constituting the electrostatic discharge protection circuit.

12. The display device of claim 11, wherein the second line is configured to receive a second voltage different from the first voltage and is electrically connected to the scan driver line and the electrostatic discharge protection circuit.

13. The display device of claim 12, wherein the electrostatic discharge protection circuit comprises at least one transistor diode-connected between the data line and the first line or the second line.

14. The display device of claim 13, wherein the at least one transistor comprises a semiconductor pattern and a gate on the semiconductor pattern, and
the bridge electrode is on a same layer as the gate.

15. The display device of claim 14, wherein the electrostatic discharge protection circuit further comprises a connection electrode over the gate and electrically connecting the gate and any one of a source area and a drain area of the semiconductor pattern.

16. The display device of claim 15, wherein the uppermost electrode comprises the connection electrode.

17. The display device of claim 15, wherein the connection electrode is on a same layer as one of the first line and the second line.

18. The display device of claim 11, wherein the line portion is on a same layer as one of the first line and the second line.

19. The display device of claim 11, wherein one of the first line and the second line, the line portion, and the uppermost electrode are on a same layer.

20. The display device of claim 11, further comprising:
a pad electrically connected to the first line,
wherein the pixel is between the pad and the electrostatic discharge protection circuit in a first direction.
